(19) United States
(12) Patent Application Publication
(10) Pub. No.: US 2015/0097249 A1
(43) Pub. Date: Apr. 9, 2015

(54) CROSS COUPLING GATE USING MULITPLE PATTERNING

(71) Applicant: GLOBALFOUNDRIES Inc., Grand Cayman (KY)

(72) Inventors: Ryan KIM, Albany, NY (US); Jason CANTONE, Mechanicville, NY (US)

(73) Assignee: GLOBALFOUNDRIES Inc., Grand Cayman (KY)

(21) Appl. No.: 14/046,351

(22) Filed: Oct. 4, 2013

(51) Int. Cl. H01L 21/8234; H01L 27/088; H01L 27/02

(52) U.S. Cl. CPC H01L 21/823475; H01L 27/0207; H01L 27/088
USPC 257/401; 438/587

(57) ABSTRACT

Methodologies for forming a cross coupling gate and a resulting device are disclosed. Embodiments include: providing a plurality of gates extending vertically on a plurality of equally spaced horizontal positions of an IC; providing a cross-couple region of a gate of the plurality of gates, the cross-couple region including a portion of the gate extending from a first horizontal position of the horizontal positions to a second horizontal position of the horizontal positions; and providing at least one of the plurality of gates with an overlap of first and second segments of the at least one gate, the first and second segments being designated to be decomposed using different colors.

### TECHNICAL FIELD

The present disclosure relates to a manufacture of semiconductor devices, such as integrated circuits (ICs). The present disclosure is particularly applicable to improving a density of features (e.g., cell utilization, reducing a number of routing layers, etc.) in an IC design and/or improving a yield of a resulting device for the 10 nanometer (nm) technology node and beyond.

### BACKGROUND

In a fabrication of semiconductor devices, a cross coupling gate is frequently used to cross couple transistors, such as P-N type transistors. However, the formation of a cross coupling gate using traditional methods often results in complexity during layout decomposition and/or design congestion in contact or routing layers (e.g., Metal1 “M1”, Metal2 “M2”, etc.), thereby resulting in IC designs and/or devices having larger cell sizes and/or an increase in a number of layers. Furthermore, use of various multiple patterning technologies, such as litho-etch-litho-etch (LELE), litho-etch-litho-etch-litho-etch (LELELE), self-aligned double patterning (SADP), directed self assembling (DSA), etc. may further exacerbate the complexity during layout decomposition, thereby resulting even larger cell sizes and/or increases in a number of layers in a resulting device.

A need therefore exists for methodologies for forming a cross coupling gate and a resulting device, particularly methodologies and devices allowing use of multiple patterning technologies.

### SUMMARY

An aspect of the present disclosure is a method of forming a cross coupling gate by, inter alia, providing a gate with an overlap (e.g., stitch) of segments being designated to be decomposed using different colors.

Another aspect of the present disclosure is a device having, inter alia, a cross-couple region of a first gate on a first horizontal position and a contact extending along a second horizontal position, the contact connecting second and third gates extending along the second horizontal position.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing a plurality of gates extending vertically on a plurality of equally spaced horizontal positions of an IC; providing a cross-couple region of a gate of the plurality of gates, the cross-couple region including a portion of the gate extending from a first horizontal position of the horizontal positions to a second horizontal position of the horizontal positions; and providing at least one of the plurality of gates with an overlap of first and second segments of the at least one gate, the first and second segments being designated to be decomposed using different colors.

Aspects include a method, wherein the at least one of the plurality of gates is the gate. Additional aspects include a method, wherein the overlap is within the cross-couple region. Further aspects include providing second and third portions of the gate on the first and second horizontal positions, respectively. Some aspects include designating the first, second, and third portions to be decomposed using a same color. Additional aspects include: providing a second gate of the plurality of gates extending along a third horizontal position of the plurality of horizontal positions, the first horizontal position separating the second and third horizontal positions; providing a third gate of the plurality of gates extending along the third horizontal position, the second and third gates being designated to be decomposed using different colors; and providing a contact extending along the third horizontal position, the contact connecting the second and third gates. Further aspects include a method, wherein providing at least one of the plurality of gates with an overlap further includes providing the first and second segments on a fourth horizontal position of the plurality of horizontal positions, the third horizontal position separating the first and fourth horizontal positions. Some aspects include providing the overlap and at least a portion of the contact in a horizontal region including the cross-couple region and a region extending horizontally from the cross-couple region.

Another aspect of the present disclosure is an apparatus including: a plurality of gates extending vertically on a plurality of equally spaced horizontal positions of an IC; a cross-couple region of a first gate of the plurality of gates, the cross-couple region including a portion of the first gate extending from a first horizontal position of the horizontal positions to a second horizontal position of the horizontal positions; a second gate of the plurality of gates extending along a third horizontal position of the plurality of horizontal positions, the third horizontal position being separated from the second horizontal position by the first horizontal position; a third gate of the plurality of gates extending along the third horizontal position; and a contact extending along the third horizontal position, the contact connecting the second and third gates.

Some aspects include an apparatus, wherein at least a portion of the contact is within a horizontal region including the cross-couple region and a region extending horizontally from the cross-couple region. Additional aspects include first and second gate contacts connecting the second and third gates to the contact, respectively. Further aspects include a fourth gate of the plurality of gates extending along a fourth horizontal position of the plurality of horizontal positions, the second horizontal position separating the first and fourth horizontal positions; a fifth gate of the plurality of gates extending along the fourth horizontal position; and a second contact extending along the fourth horizontal position, the second contact connecting the fourth and fifth gates. Some aspects include third and fourth gate contacts connecting the fourth and fifth gates to the second contact, respectively. Further aspects include an apparatus, wherein the first and second horizontal positions are adjacent, the first and third horizontal positions are adjacent, and the second and fourth horizontal positions are adjacent. Additional aspects include an apparatus, wherein the first and second contacts each extend a distance at least twice a separation distance between adjacent horizontal positions of the horizontal positions. Some aspects include an apparatus, wherein the distance the first and second contacts each extend is less than five times the separation distance.

Another aspect of the present disclosure is a method including: providing a plurality of gates extending vertically on a plurality of equally spaced horizontal positions of an IC; providing a cross-couple region of a first gate of the plurality of gates, the cross-couple region including a portion of the first gate extending from a first horizontal position of the horizontal positions to a second horizontal position of the horizontal positions; designating first and second portions of the first gate adjacent the cross-couple region on the first and second horizontal positions, respectively, to be decomposed using a same color, the first and second horizontal positions being adjacent; providing a second gate of the plurality of gates extending along a third horizontal position of the plurality of horizontal positions, the first and third horizontal positions being adjacent; providing a third gate of the plurality of gates extending along the third horizontal position, the second and third gates being designated to be decomposed using different colors and being separated; providing a first segment of a fourth gate of the plurality of gates on a fourth horizontal position of the plurality of horizontal positions, the third and fourth horizontal positions being adjacent; and providing a second segment of the fourth gate on the fourth horizontal position, the first and second segments being designated to be decomposed using different colors, wherein the first and second segments overlap in a horizontal region including the cross-couple region and a region extending horizontally from the cross-couple region.

Some aspects include: providing a contact extending along the third horizontal position, wherein at least a portion of the contact is within the horizontal region; and providing first and second gate contacts connecting the second and third gates to the contact, respectively. Additional aspects include: providing a fifth gate of the plurality of gates extending along a fifth horizontal position of the plurality of horizontal positions, the second and fifth horizontal positions being adjacent; providing a sixth gate of the plurality of gates extending along the fifth horizontal position; and providing a second contact extending along the fifth horizontal position, wherein at least a portion of the second contact is within the horizontal region; and providing third and fourth gate contacts connecting the fifth and sixth gates to the second contact, respectively. Further aspects include: providing a first segment of a seventh gate of the plurality of gates on a sixth horizontal position of the plurality of horizontal positions, the fifth and sixth horizontal positions being adjacent; and providing a second segment of the seventh gate on the sixth horizontal position, the first and second segments of the seventh gate being designated to be decomposed using different colors, wherein the first and second segments of the seventh gate overlap in the horizontal region.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 illustrates a cross coupling gate, in accordance with an exemplary embodiment;

FIG. 2 is a flowchart of a process for forming a cross coupling gate, according to an exemplary embodiment;

FIGS. 3 through 5 illustrate a process for forming a cross coupling gate, in accordance with an exemplary embodiment; and

FIGS. 6 and 7 illustrate another process for forming a cross coupling gate, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problems of design congestion and layout decomposition complexity, resulting in large cell size and an increased number of layers, attendant upon forming cross coupling gates, particularly in IC designs utilizing multiple patterning technologies. In accordance with embodiments of the present disclosure, the problems are solved, for instance by, inter alia, providing a gate with an overlap of segments being designated to be decomposed using different colors.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

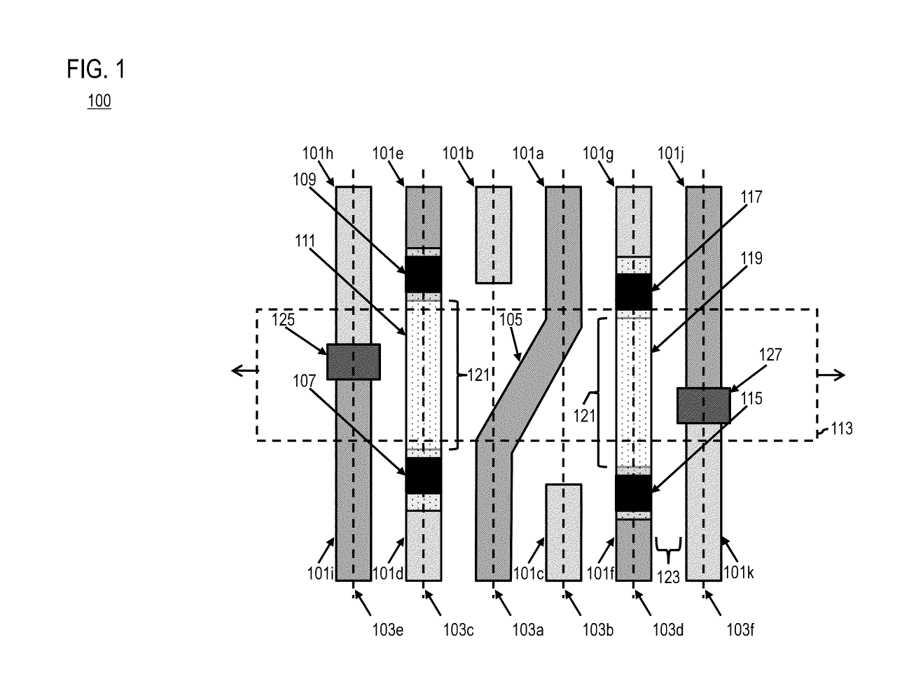

Adverting to FIG. 1, gates 101a through 101k extend vertically on equally spaced horizontal positions 103a through 103f of an IC 100. As shown, the gate 101a has a portion 105 extending, in a cross-couple region, from horizontal position 103a to horizontal position 103b. Additionally, FIG. 1 illustrates gates 101d and 101e connected via gate contacts 107 and 109, respectively, to contact 111 extending along horizontal position 103c. The contact 111 may be a vertical strap contact at a different integration height than the gates 101a through 101k. As shown, the portion 105 is within a horizontal region 113 including the cross-couple region and a region extending horizontally from the cross-couple region.

Additionally, FIG. 1 includes gates 101f and 101g connected via gate contacts 115 and 117, respectively, to a contact 119 extending along horizontal position 103d. As shown, a portion of the contacts 111 and 119 is within horizontal region 113. Additionally, the contacts 111 and 119 each extend a distance 121 at least twice a separation distance 123 between adjacent horizontal positions of the horizontal positions 103a through 103f and the distance 121 is less than five times the separation distance 123. Furthermore, as shown, gates 101h and 101i and gates 101j and 101k on horizontal positions 103e and 103f, respectively, include overlaps 125 and 127, respectively. The overlaps 125 and 127 may be used to stitch segments decomposed using different colors of a multiple patterning process, to increase an overlap area to improve yield of a resulting device, identify a region as a landing pad of a contact, or a combination thereof.

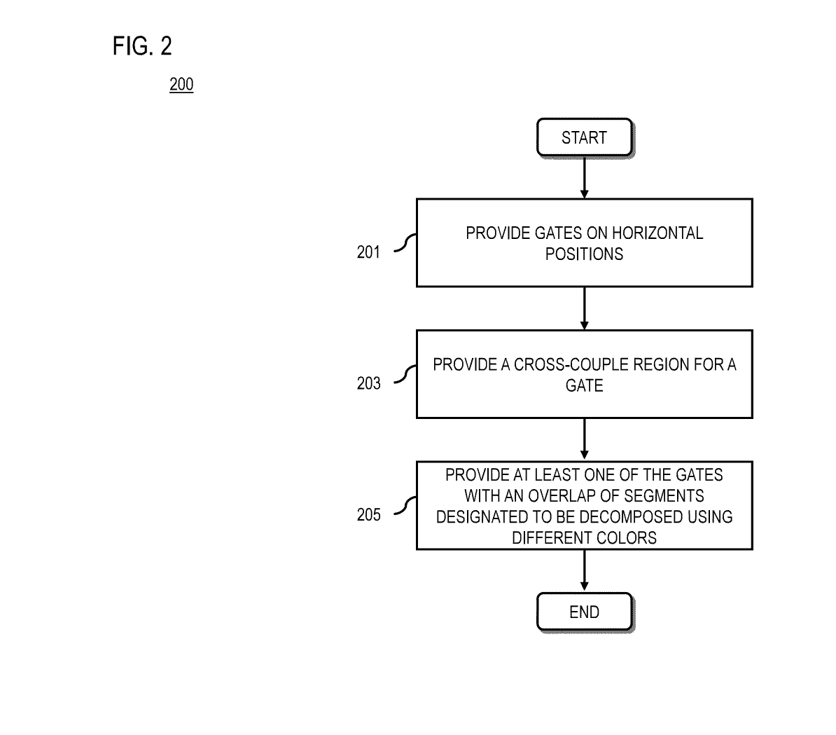

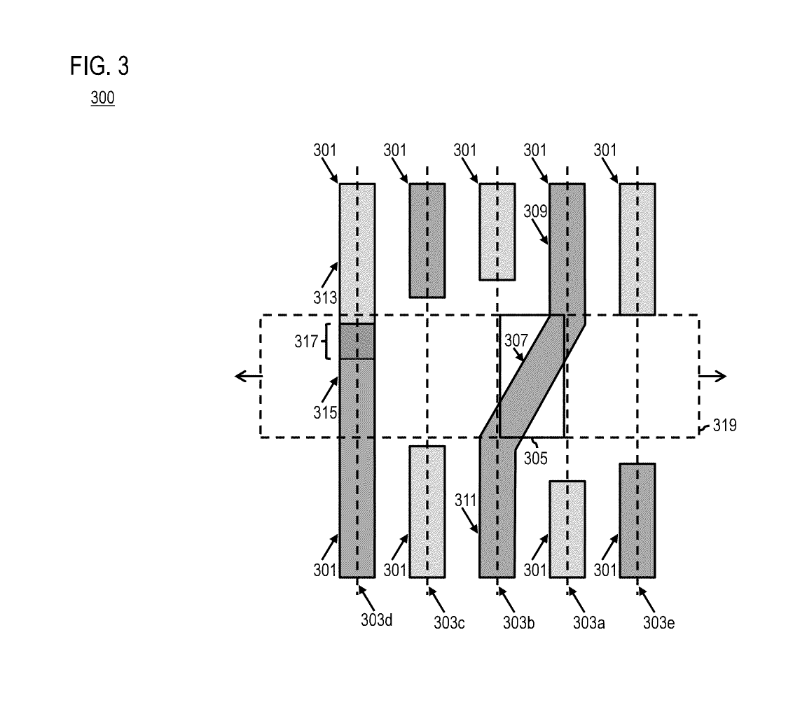

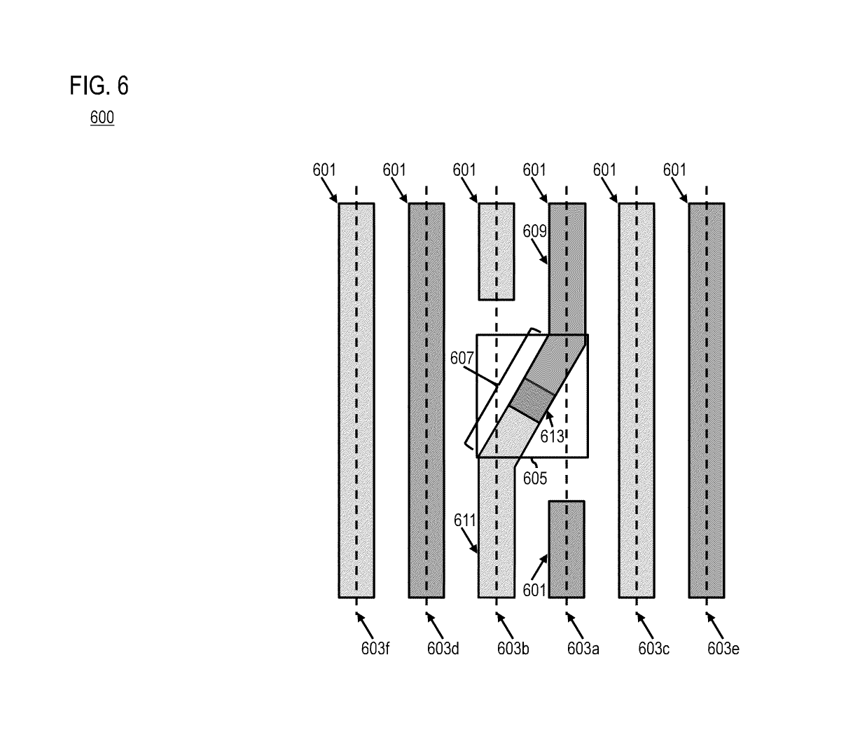

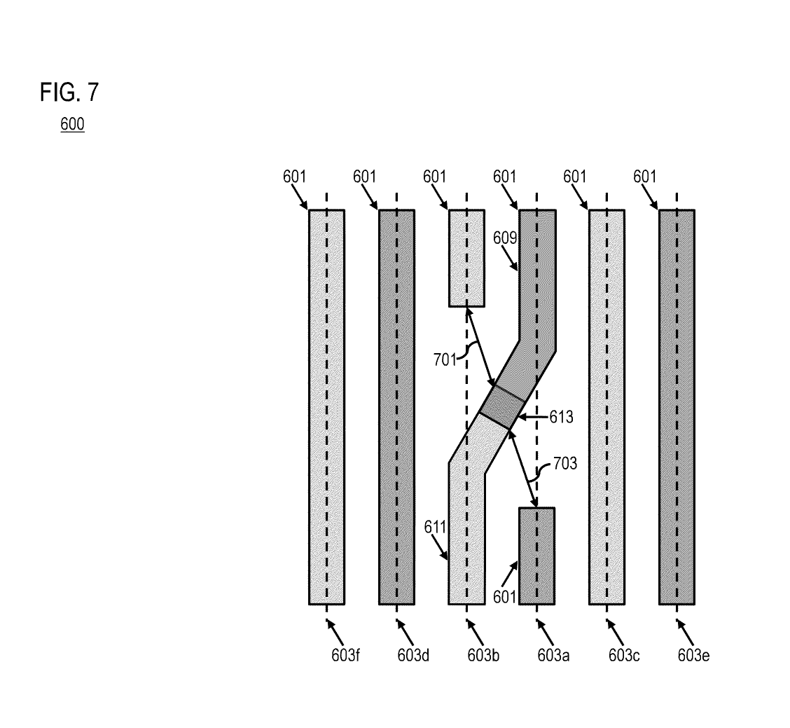

FIG. 2 is a flowchart of a process for forming a cross coupling gate, according to an exemplary embodiment. For illustrative purposes, process 200 is illustrated by a first example in the steps of FIGS. 3 through 5 and a second example in the steps of FIGS. 6 and 7. It is noted that the steps of process 200 may be performed in any suitable order, as well as combined or separated in any suitable manner.

Adverting to FIG. 3, gates 301 are provided, as in step 201, on horizontal positions 303a through 303e of IC 300. As shown, the gates 301 are designated to be decomposed in multiple colors, for instance, gates 301 are designated to be decomposed using mandrel and non-mandrel regions of a SADP process. It is contemplated that the gates 301 may be formed using multiple colors of various other multiple patterning processes including LELE, LELELE, DSA, and the like.

Next, in step 203, a cross-couple region of one gate is provided, the cross-couple region including a portion of the gate extending from a first horizontal position to a second horizontal position. For instance, cross-couple region 305 includes a portion 307 of a gate 301 extending from a horizontal position 303a to a horizontal position 303b, the gate 301 having portions 309 and 311 provided on the horizontal positions 303a and 303b, respectively. As shown, the portions 307 through 311 are designated to be decomposed using a same color.

In step 205, at least one of the gates is provided with an overlap of first and second segments of the at least one gate, the first and second segments being designated to be decomposed using different colors. For instance, segments 313 and 315 are provided on horizontal position 303d with overlap 317 provided in horizontal region 319 extending horizontally from the cross-couple region 305. The overlap 317 may be used to stitch segments 313 and 315, to increase an overlap area to improve yield of a resulting device, identify a region as a landing pad of a contact, or a combination thereof.

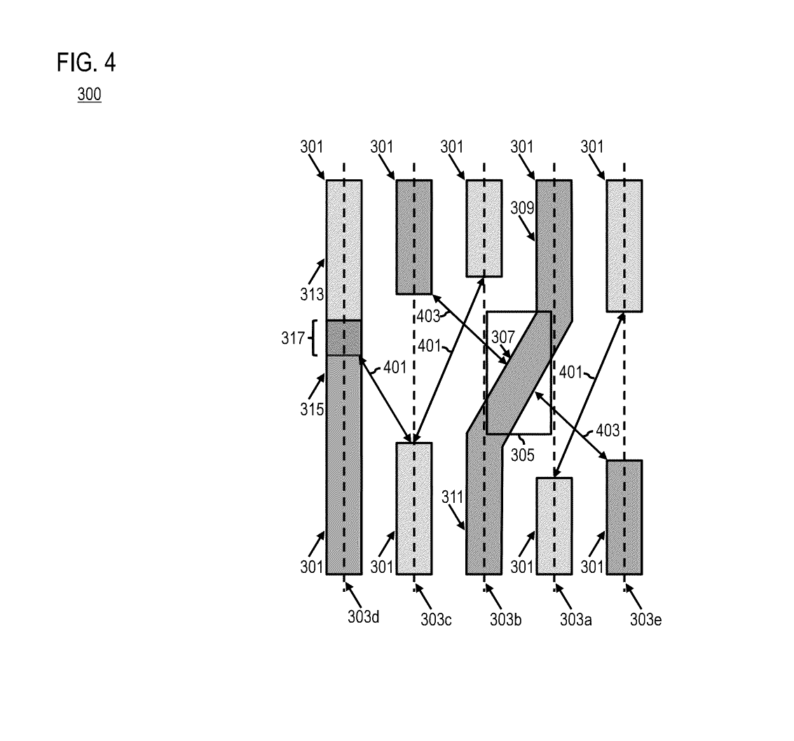

Adverting to FIG. 4, a separation distance between gates of the same color is maintained. As shown, the overlap 317 is sized such that separation distances 401 and 403 between gates 301 are within a threshold value, such as, for example, a side-to-side minimum separation distance for features of the same color.

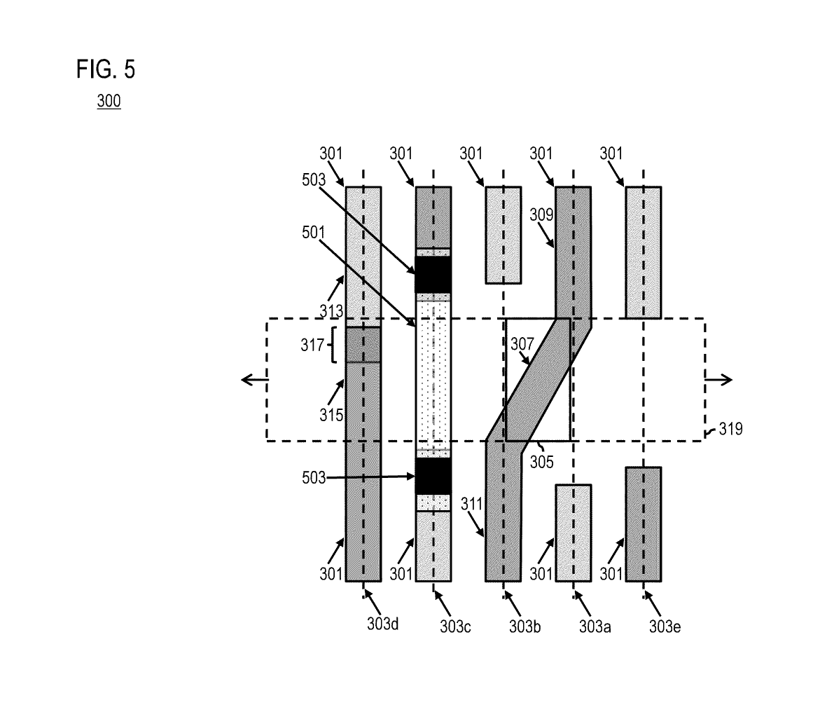

Adverting to FIG. 5, a contact 501 is optionally provided on horizontal position 303c connecting gates 301 extending on the horizontal position 303c. As shown, the contact 501 is connected to the gates 301 by gate contacts 503.

Adverting to FIG. 6, gates 601 are provided, as in step 201, on horizontal positions 603a through 603f of IC 600. As shown, the gates 601 are designated to be decomposed in multiple colors, for instance, gates 601 are designated to be decomposed using first and second (and third) Litho-Etch steps of an LELE (or LELELE) process. It is contemplated that the gates 601 may be formed using multiple colors of various other processes including SADP, DSA, and the like.

Next, in step 203, a cross-couple region of one gate is provided, the cross-couple region including a portion of the gate extending from a first horizontal position to a second horizontal position. For instance, cross-couple region 605 includes a portion 607 of one of the gates 601 extending from horizontal position 603a to horizontal position 603b.

In step 205, at least one of the gates is provided with an overlap of first and second segments of the at least one gate, the first and second segments being designated to be decomposed using different colors. For instance, segments 609 and 611 are provided with an overlap 613 within the cross-couple region 605. The overlap 613 may be used to stitch segments 609 and 611, to increase an overlap area to improve yield of a resulting device, identify a region as a landing pad of a contact, or a combination thereof.

Adverting to FIG. 7, a separation distance between gates of the same color is maintained. As shown, the overlap 613 is sized such that separation distances 701 and 703 between gates 601 are within a threshold value, such as, for example, a tip-to-tip minimum separation distance for features of the same color.

The embodiments of the present disclosure can achieve several technical effects, including an improvement in a density of features (e.g., smaller cell sizes, fewer layers, etc.) of an IC. The present disclosure enjoys industrial applicability in any of various types of highly integrated semiconductor devices utilizing multiple patterning technologies, particularly for the 10 nm technology node and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
providing a plurality of gates extending vertically on a plurality of equally spaced horizontal positions of an integrated circuit (IC);
providing a cross-couple region of a gate of the plurality of gates, the cross-couple region including a portion of the gate extending from a first horizontal position of the horizontal positions to a second horizontal position of the horizontal positions; and
providing at least one of the plurality of gates with an overlap of first and second segments of the at least one gate, the first and second segments being designated to be decomposed using different colors.

2. The method according to claim 1, wherein the at least one of the plurality of gates is the gate.

3. The method according to claim 2, wherein the overlap is within the cross-couple region.

4. The method according to claim 1, further comprising:
providing second and third portions of the gate on the first and second horizontal positions, respectively.

5. The method according to claim 4, further comprising:
designating the first, second, and third portions to be decomposed using a same color.

6. The method according to claim 4, further comprising:
providing a second gate of the plurality of gates extending along a third horizontal position of the plurality of horizontal positions, the first horizontal position separating the second and third horizontal positions;
providing a third gate of the plurality of gates extending along the third horizontal position, the second and third gates being designated to be decomposed using different colors; and
providing a contact extending along the third horizontal position, the contact connecting the second and third gates.

7. The method according to claim 6, wherein providing at least one of the plurality of gates with an overlap further comprises:
providing the first and second segments on a fourth horizontal position of the plurality of horizontal positions, the third horizontal position separating the first and fourth horizontal positions.

8. The method according to claim 6, further comprising:
providing the overlap and at least a portion of the contact in a horizontal region comprising the cross-couple region and a region extending horizontally from the cross-couple region.

9. An apparatus comprising:
a plurality of gates extending vertically on a plurality of equally spaced horizontal positions of an integrated circuit (IC);
a cross-couple region of a first gate of the plurality of gates, the cross-couple region including a portion of the first gate extending from a first horizontal position of the horizontal positions to a second horizontal position of the horizontal positions;
a second gate of the plurality of gates extending along a third horizontal position of the plurality of horizontal positions, the third horizontal position being separated from the second horizontal position by the first horizontal position;
a third gate of the plurality of gates extending along the third horizontal position; and
a contact extending along the third horizontal position, the contact connecting the second and third gates.

10. The apparatus according to claim 9, wherein at least a portion of the contact is within a horizontal region comprising the cross-couple region and a region extending horizontally from the cross-couple region.

11. The apparatus according to claim 9, further comprising:
first and second gate contacts connecting the second and third gates to the contact, respectively.

12. The apparatus according to claim 11, further comprising:
a fourth gate of the plurality of gates extending along a fourth horizontal position of the plurality of horizontal positions, the second horizontal position separating the first and fourth horizontal positions;
a fifth gate of the plurality of gates extending along the fourth horizontal position; and
a second contact extending along the fourth horizontal position, the second contact connecting the fourth and fifth gates.

13. The apparatus according to claim 12, further comprising:
third and fourth gate contacts connecting the fourth and fifth gates to the second contact, respectively.

14. The apparatus according to claim 12, wherein the first and second horizontal positions are adjacent, the first and third horizontal positions are adjacent, and the second and fourth horizontal positions are adjacent.

15. The apparatus according to claim 12, wherein the first and second contacts each extend a distance at least twice a separation distance between adjacent horizontal positions of the horizontal positions.

16. The apparatus according to claim 15, wherein the distance the first and second contacts each extend is less than five times the separation distance.

17. A method comprising:
providing a plurality of gates extending vertically on a plurality of equally spaced horizontal positions of an integrated circuit (IC);
providing a cross-couple region of a first gate of the plurality of gates, the cross-couple region including a portion of the first gate extending from a first horizontal position of the horizontal positions to a second horizontal position of the horizontal positions;
designating first and second portions of the first gate adjacent the cross-couple region on the first and second horizontal positions, respectively, to be decomposed using a same color, the first and second horizontal positions being adjacent;
providing a second gate of the plurality of gates extending along a third horizontal position of the plurality of horizontal positions, the first and third horizontal positions being adjacent;
providing a third gate of the plurality of gates extending along the third horizontal position, the second and third gates being designated to be decomposed using different colors and being separated;
providing a first segment of a fourth gate of the plurality of gates on a fourth horizontal position of the plurality of horizontal positions, the third and fourth horizontal positions being adjacent; and
providing a second segment of the fourth gate on the fourth horizontal position, the first and second segments being designated to be decomposed using different colors, wherein the first and second segments overlap in a horizontal region comprising the cross-couple region and a region extending horizontally from the cross-couple region.

18. The method according to claim 17, further comprising:
providing a contact extending along the third horizontal position, wherein at least a portion of the contact is within the horizontal region; and
providing first and second gate contacts connecting the second and third gates to the contact, respectively.

19. The method according to claim 18, further comprising:
providing a fifth gate of the plurality of gates extending along a fifth horizontal position of the plurality of horizontal positions, the second and fifth horizontal positions being adjacent;
providing a sixth gate of the plurality of gates extending along the fifth horizontal position; and
providing a second contact extending along the fifth horizontal position, wherein at least a portion of the second contact is within the horizontal region; and
providing third and fourth gate contacts connecting the fifth and sixth gates to the second contact, respectively.

20. The method according to claim 19, further comprising:
providing a first segment of a seventh gate of the plurality of gates on a sixth horizontal position of the plurality of horizontal positions, the fifth and sixth horizontal positions being adjacent; and
providing a second segment of the seventh gate on the sixth horizontal position, the first and second segments of the seventh gate being designated to be decomposed using different colors, wherein the first and second segments of the seventh gate overlap in the horizontal region.
